(19) United States
(12) Patent Application Publication
(10) Pub. No.: US 2001/0015917 A1
(43) Pub. Date: Aug. 23, 2001

(54) Recording medium having data recorded in data structure capable of editing additional data related to audio data, method and apparatus of recording and/or reproducing thereof

(76) Inventors: Jung-Kwon Heo, Seoul (KR); Seong-Jin Moon, Suwon-city (KR)

Correspondence Address: STAAS & HALSEY LLP, 700 11TH STREET, NW, SUITE 500, WASHINGTON, DC, 20001, US

(21) Appl. No.: 09/736,160

(22) Filed: Dec. 15, 2000

Related U.S. Application Data
(60) Provisional application No. 60/246,102, filed on Nov. 7, 2000.

(30) Foreign Application Priority Data
Dec. 31, 1999 (KR) 99-67801
Nov. 23, 2000 (KR) 00-70007

(51) Int. Cl. G11C 7/00

(52) U.S. Cl. 365/200

(57) ABSTRACT

A recording medium having data recorded in a data structure capable of editing additional data related to audio data, a method and an apparatus for recording and/or reproducing thereof. The recording medium in which audio data is recorded in units of predetermined recording units and additional data related to the audio data is recorded in a predetermined location in the recording unit of the audio data makes recording/editing/reproducing of the audio data and the additional data related to the audio data easier. Therefore, a user can additionally record additional information such as a text in audio data, and can reproduce the additional information together with the audio data.

### CROSS-REFERENCE TO RELATED APPLICATIONS

This application claims the benefit of Korean Application Nos. 99-67801, filed Dec. 31, 1999 and 00-70007, filed Nov. 23, 2000, in the Korean Patent Office and U.S. Provisional Application No. 60/246,102, filed Nov. 7, 2000 in the United States, the disclosures of which are incorporated herein by reference.

### BACKGROUND OF THE INVENTION

1. Field of the Invention

The present invention relates to digital data recording and/or reproducing, and more particularly, to a recording medium on which data is recorded in a data structure capable of editing additional data to be reproduced together with audio data, and a method and an apparatus for recording and/or reproducing using the data structure.

2. Description of the Related Art

In recording digital audio data on a recording medium such as an optical disc in conventional ways, for example, when a plurality of songs are recorded, each song is usually recorded on one track, and audio data for each song is recorded in each track. Meanwhile, in conventional ways, when additional data related to audio data is desired to be recorded, additional data is multiplexed together with the audio data, and, for example, is recorded as a moving picture experts group (MPEG) stream. Therefore, the additional data recorded together with the audio data can be reproduced together, but it is substantially impossible to edit the additional data alone. That is, additional information, which should be reproduced simultaneously with related audio data, cannot be recorded after the audio data is recorded, or cannot be modified or deleted separately from the audio data.

### SUMMARY OF THE INVENTION

To solve the above problems, it is an object of the present invention to provide a recording medium recorded in a data structure capable of editing additional data related to audio data, and a method and an apparatus for recording and/or reproducing thereof.

It is another object of the present invention to provide a recording medium on which audio data is recorded in units of predetermined recording units, and additional data related to the audio data is recorded by a data structure capable of editing the additional data related to the recording units of the audio data, and a method and an apparatus for recording and/or reproducing thereof.

It is another object to provide a method of simultaneously reproducing audio data and additional data from a recording medium on which audio data is recorded in units of predetermined recording units and additional data related to the audio data is recorded in units of recording units which can be edited so that the additional data relates to the recording unit of the audio data.

Additional objects and advantages of the invention will be set forth in part in the description which follows and, in part, will be obvious from the description, or may be learned by practice of the invention.

To accomplish the above and other objects of the present invention, there is provided a recording medium in which audio data is recorded in units of predetermined recording units and additional data related to the audio data is recorded in a predetermined location in the recording unit of the audio data.

To accomplish the above and other objects of the present invention, there is still also provided a recording method of recording audio data and additional data related to the audio data, the recording method comprising recording audio data in units of predetermined recording units; and (b) recording the additional data in a predetermined location in the recording unit.

To accomplish the above and other objects of the present invention, there is still also provided a reproducing method of reproducing data from a recording medium in which audio data is recorded in units of predetermined recording units and additional data related to the audio data is recorded in a predetermined location in the recording unit of the audio data, the reproducing method comprising reading data in units of the recording units; and (b) reproducing audio data and additional data recorded in the read recording unit, after relating the additional data to the audio data.

To accomplish the above and other objects of the present invention, there is still yet also provided a recording apparatus having an audio signal processor encoding input audio data to generate an audio pack, and combining at least one generated audio pack to generate an audio object unit (AOBU) that is a predetermined recording unit; a real-time text information (RTI) signal processor encoding additional data related to the audio data to generate an RTI pack; a multiplexor generating an AOBU having additional data by including the RTI pack provided from the RTI signal processor in an AOBU provided from the audio signal processor; and a recording controller recording the AOBU generated by the multiplexor.

To accomplish the above and other objects of the present invention, there is still yet also provided a reproducing apparatus for reproducing data from a recording medium in which audio data is recorded in units of predetermined recording units and additional data related to the audio data is recorded in a predetermined location in the recording unit of the audio data, the reproducing apparatus comprising a reproducing controller reading an audio object unit (AOBU) which is a recording unit; a demultiplexor demultiplexing an audio pack in which audio data is recorded and an RTI pack in which additional data is recorded, from the read AOBU; an audio signal processor decoding the audio pack demultiplexed by the demultiplexor to output audio data; and an RTI signal processor decoding the RTI pack demultiplexed by the demultiplexor to output additional data in relation to the audio data.

To accomplish the above and other objects of the present invention, there is still yet also provided a recording and/or reproducing apparatus having an audio signal processor encoding input audio data to generate an audio pack and combining at least one generated audio pack to generate an audio object unit (AOBU) which is a predetermined recording unit, when data is recorded; and decoding an audio pack demultiplexed from the AOBU by a demultiplexor to output audio data, when data is reproduced; a real-time text information (RTI) signal processor encoding additional data related to the audio data to generate an RTI pack which is an additional pack when data is recorded; and decoding an RTI pack demultiplexed from the AOBU by the demultiplexor to output the additional data in relation to the audio data when data is reproduced; a multiplexor/demultiplexor including the RTI pack provided from the RTI signal processor in the AOBU provided from the audio signal processor to generate an AOBU having additional data, and when data is reproduced, demultiplexing an audio pack in which audio data is recorded and an RTI pack in which additional data is recorded, from the read AOBU; and a recording/reproducing controller recording the AOBU generated by the multiplexor in a recording medium, reading the AOBU which is a recording unit from the recording medium, and providing the AOBU to the audio signal processor and the RTI signal processor.

### BRIEF DESCRIPTION OF THE DRAWINGS

The above and other objects and advantages of the present invention will become more apparent by describing in detail a preferred embodiment thereof with reference to the attached drawings in which:

FIG. 1 is an example of a data structure recorded on a recording medium according to the present invention;

FIG. 2 is another example of a data structure recorded on a recording medium according to the present invention;

FIG. 3 is a block diagram of a recording apparatus according to an embodiment of the present invention;

FIG. 4 is a block diagram of a reproducing apparatus according to an embodiment of the present invention;

FIG. 5 is a block diagram of a recording and/or reproducing apparatus according to an embodiment of the present invention;

FIG. 6 is a flowchart showing a recording method according to an embodiment of the present invention; and

FIG. 7 is flowchart showing a reproducing method according to an embodiment of the present invention.

### DETAILED DESCRIPTION OF THE PREFERRED EMBODIMENTS

Hereinafter, embodiments of the present invention will be described in detail with reference to the attached drawings. The present invention is not restricted to the following embodiments, and many variations are possible within the spirit and scope of the present invention. The embodiments of the present invention are provided in order to more completely explain the present invention to anyone skilled in the art.

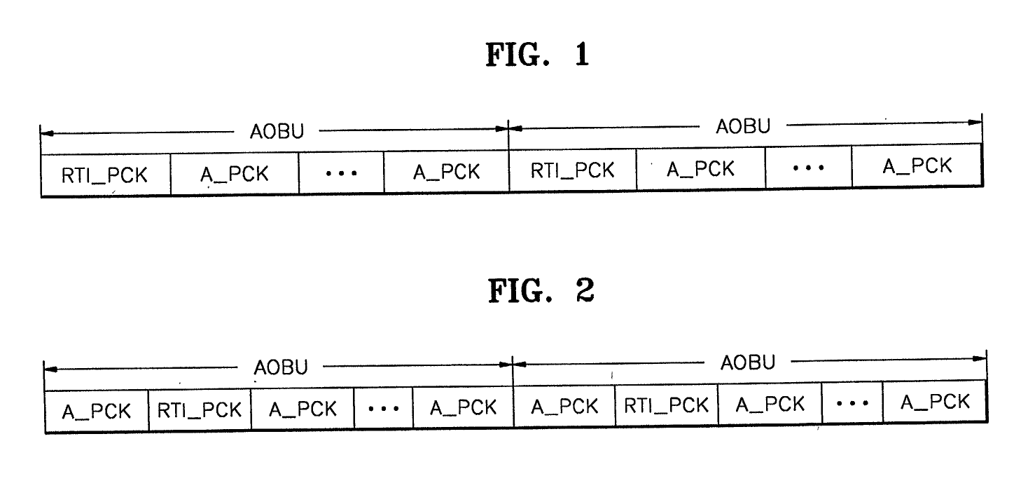

FIG. 1 is an example of a data structure recorded on a recording medium according to the present invention.

Referring to FIG. 1, audio data is recorded in units of audio object units (AOBUs) each of which is a basic recording unit that can be edited. An AOBU has at least one or more audio packs A_PCKS. An audio pack A_PCK has an audio data part and an extra header part. In the extra header, synchronization information of audio data is recorded.

In the audio pack A_PCK, audio data and related additional data can be recorded together, but in this case, it is difficult to add and modify audio data or additional data. Therefore, additional data related to audio data is recorded separately from the audio pack. More specifically, according to the present embodiment, additional data is recorded as an independent pack, referred to as a real-time text information (RTI) pack RTI_PCK, in the front part of an AOBU. Also, the RTI pack RTI_PCK can have an additional data part and an extra header part. In the extra header part, information such as synchronization information required to reproduce the additional data is recorded.

FIG. 2 is another example of a data structure recorded on a recording medium according to the present invention.

As the data structure shown in FIG. 1, the structure of an AOBU shown in FIG. 2 has at least one or more audio packs A_PCKs in the AOBU, and additional data is recorded as a separate, independent RTI pack RTI_PCK. However, the location of the RTI pack is different from that of the RTI pack RTI_PCK in FIG. 1. Referring to FIG. 2, the RTI pack RTI_PCK is located next to an audio pack A_PCK located in the front of the AOBU.

Since an RTI pack RTI_PCK has additional data which is to be synchronized to an audio pack A_PCK and reproduced, if only the RTI pack RTI_PCK is recorded on a location where the RTI pack can be synchronized to an audio pack A_PCK included in the AOBU and reproduced, the location of the RTI pack RTI_PCK can change depending on necessity. Also, an AOBU, in which no additional data to be reproduced in relation to an audio pack A_PCK exist, has an RTI pack RTI_PCK in which no data is recorded.

As shown in FIGS. 1 and 2, if additional data is recorded as an independent RTI pack RTI_PCK inside an AOBU that is an audio recording unit, modification and editing of additional data can be easily done. Because, if modification or editing of additional data is needed, such jobs can be done by only changing data in the location of an RTI pack RTI_PCK, after finding an AOBU including the RTI pack RTI_PCK. That is, when audio data (recorded as an AOBU) is modified, additional data can be modified and/or edited together with the audio data in the AOBU. Therefore, according to the present invention, since additional data is independently recorded inside an AOBU which is a basic recording unit of main data (here, audio data), modification of additional data can be done by only modifying main data. In other words, additional data recorded in an RTI pack RTI_PCK may be accessed and modified in the same way in which main data contained in an AOBU is accessed and modified. Furthermore, data recorded in an RTI pack RTI_PCK may be accessed and modified together with main data contained in the corresponding AOBU.

If additional data to be recorded in an RTI pack is real-time data, that is, data that should be reproduced with respect to a reproducing timing of audio data, the reproducing-start time of the additional data, as synchronization information to be recorded in an extra header of an RTI pack, is placed on a location between the reproducing-start time of the AOBU and the reproducing-end time of the AOBU, that is, on a reproducing duration.

When additional data recorded as an RTI pack is text data, that is, when a text which a user input is real-time text data which the user wants to reproduce together with related audio data, the corresponding text is encoded to generate an RTI pack, and the generated RTI pack is recorded in a predetermined location of the AOBU. A reproducing-start time of text data designated by the user is placed in a location between the reproducing-start time of the AOBU and the reproducing-end time of the AOBU. The reproducing-start time and the reproducing-end time are likely to be recorded in a header information part of an AOBU but may be recorded at any other recording area.

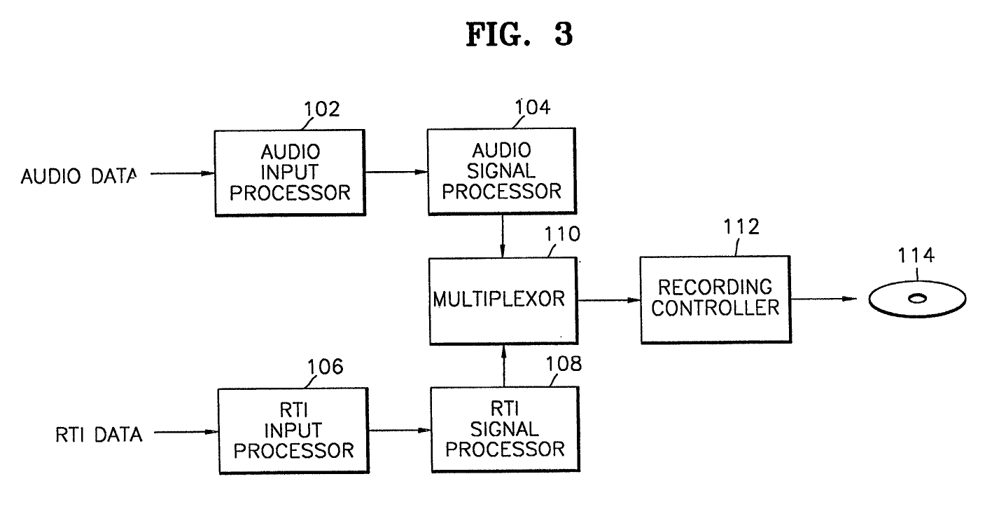

FIG. 3 is a block diagram according to an embodiment of the recording apparatus of the present invention.

Referring to FIG. 3, an audio input processor 102 pre-processes input audio data, an audio signal processor 104 formats audio data to form a data pack, and encodes the formed data pack to generate an audio pack (A_PCK). By combining at least one or more generated audio packs, an independent audio object unit (AOBU) that can be edited as a basic recording unit is generated.

An RTI input processor 106 pre-processes RTI data having additional data related to audio data, and an RTI signal processor 108 formats RTI data to form a data pack, and encodes the formed data pack to generate an RTI pack (RTI_PCK).

A multiplexor 110 generates an AOBU having an RTI pack, by including the RTI pack provided from the RTI signal processor 108, in a predetermined location inside an AOBU provided from the audio signal processor 104. A recording controller 112 records audio data on a recording medium 114 in units of AOBUs generated by the multiplexor 110. When it is not necessary for the reproduction of additional data recorded in an RTI pack RTI_PCK to begin at a specific predetermined time, proceed in synchronization with audio data included in the corresponding AOBU and end at a specific predetermined time, the RTI pack RTI_PCK can be located anywhere inside the AOBU. In other words, when it is not necessary that an RTI pack RTI_PCK be at a particular position in the sequence of data packs included in the corresponding AOBU, the RTI pack RTI_PCK can be located anywhere inside the AOBU. However, when it is assumed that data packs included in the corresponding AOBU are sequentially read and reproduced, it is preferable that an RTI pack RTI_PCK is located in the front of the corresponding AOBU, considering a case in which additional data recorded in an RTI pack RTI_PCK should be synchronized to an audio pack in the front part of the corresponding AOBU and sequentially reproduced.

In an RTI pack RTI_PCK, real-time text data is recorded. In an audio pack A_PCK, audio data is recorded. Real-time text data is a text provided to a user by being synchronized to audio data and reproduced. For example, additional information on a song, such as the characteristic, the lyric, the composer, etc., is recorded in the form of a text.

In an RTI pack RTI_PCK in which text data is recorded, reproducing time information of the corresponding text is further recorded. Also, the reproducing-start time of additional data included in the RTI pack RTI_PCK is located between the reproducing-start time of the corresponding AOBU and the reproducing-end time of the AOBU.

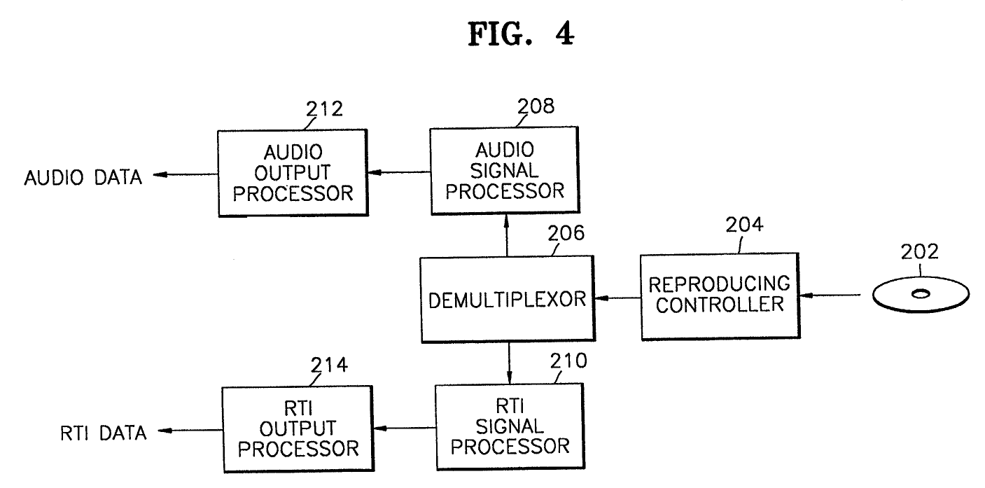

FIG. 4 is a block diagram according to an embodiment of the reproducing apparatus of the present invention.

Referring to FIG. 4, a reproducing controller 204 reads data in units of AOBUs each of which has the data structure shown in FIG. 1 or 2 from a recording medium 202 and provides the AOBUs to a demultiplexor 206. After checking the kind of pack in the read AOBU, if the pack is an RTI pack RTI_PCK, the demultiplexor 206 provides the RTI pack RTI_PCK data to an RTI signal processor 210, and if the pack is an audio pack A_PCK, provides the audio pack A_PCK to an audio signal processor 208.

The audio signal processor 208 decodes the audio pack A_PCK data, deformats the decoded audio data, and provides the audio data to an audio output processor 210.

The RTI signal processor 214 decodes the RTI pack RTI_PCK data, deformats the decoded RTI pack RTI_PCK data, and provides the RTI data to an RTI output processor 214. Here, the RTI signal processor 212 outputs text data stored in the RTI pack RTI_PCK, after synchronizing the text data to audio data output from the audio signal processor 208, based on corresponding reproducing time information.

The audio output processor 212 processes input signals so that the signals can be applied to external output devices such as a speaker. The RTI output processor 214 signal-processes input real-time text data so that the text data can be applied to external devices such as a monitor.

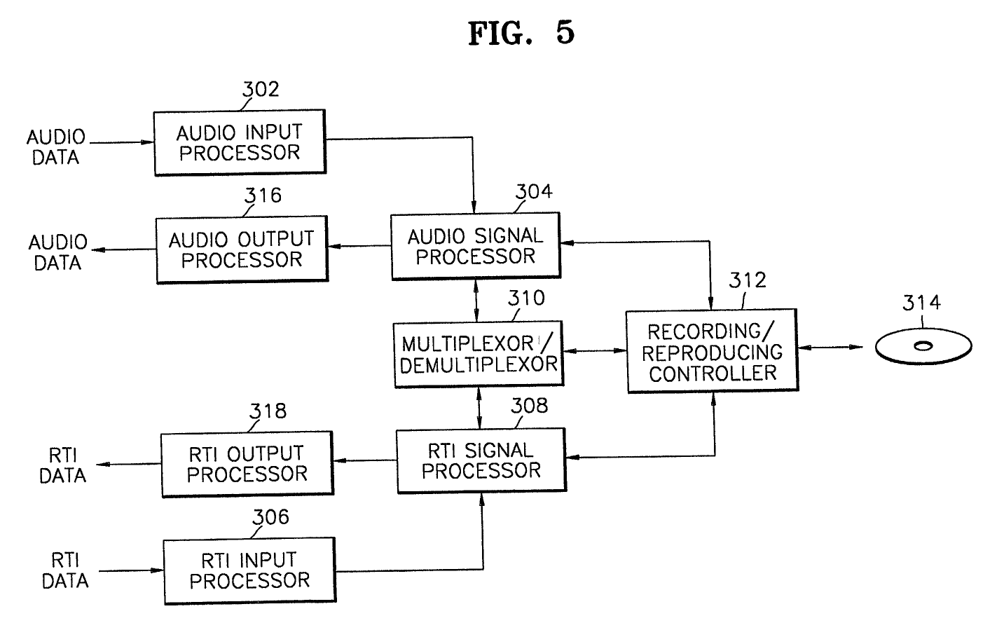

FIG. 5 is a block diagram of a recording and/or reproducing apparatus according to an embodiment of the present invention.

When the recording apparatus of FIG. 3 and the reproducing apparatus of FIG. 4 are integrated, an audio signal processor 304, an RTI signal processor 308, a multiplexor/demultiplexor 310, and a recording and/or reproducing controller 312 are not separately formed but uniformly formed in FIG. 5. Except for this point, an audio input processor 302, an RTI input processor 306, an audio output processor 316, and an RTI output processor 318 are the same those as shown in FIGS. 3 and 4, and therefore a redundant explanation on these structures and operations will be omitted.

When data is recorded, the audio signal processor 304 formats audio data to form a data pack, and encodes the formed data pack to generate an audio pack A_PCK. By combining at least one or more generated audio packs A PCKs, an independent audio object unit (AOBU) that can be edited as a basic recording unit is generated. The RTI signal processor 308 formats RTI data, in which additional data is recorded, to generate a data pack, and encodes the formed data pack to generate an RTI pack RTI_PCK.

The multiplexor/demultiplexor 310 generates a new AOBU by including an RTI pack RTI_PCK provided from the RTI signal processor 308, in a predetermined location inside the AOBU. The recording and/or reproducing controller 312 records data in units of newly generated AOBUs.

When data is reproduced, the recording and/or reproducing controller 312 reads data in units of new AOBUs from the recording medium 314, and provides the data to the multiplexor/demultiplexor 310. The multiplexor/demultiplexor 310, if the read AOBU pack is an RTI pack RTI_PCK, provides the RTI pack RTI_PCK to the RTI signal processor 308, and, if the read AOBU pack is an audio pack A_PCK, provides the audio pack A_PCK to the audio signal processor 304.

The audio signal processor 308 decodes the audio pack A_PCK, deformats the decoded audio pack A_PCK, and provides the audio pack A_PCK to the audio output processor 316. The RTI signal processor 308 decodes the RTI pack RTI_PCK, deformats the decoded RTI pack RTI_PCK, and provides the RTI pack RTI_PCK to the RTI output processor 318.

As the recording and/or reproducing apparatus has two operating modes (a recording mode and a reproducing mode), the audio signal processor 304, the multiplexer/demultiplexor 310, and the RTI signal processor 308, in addition to the recording/reproducing controller 312, each has two operating modes, and they can transmit and receive signals to inform each other of a change in operating mode.

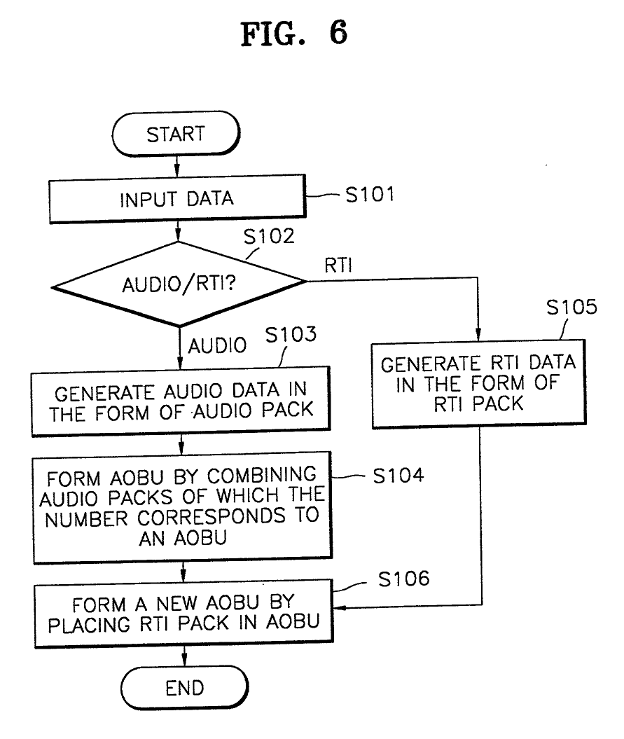

FIG. 6 is a flowchart showing an embodiment of a recording method according to an embodiment of the present invention.

Referring to FIG. 6, data is input in step S101, and whether input data is audio data or RTI data is determined in step S102. If the input data is audio data, the audio data is processed to form an audio pack A_PCK in step S103, and by combining audio packs A_PCKs of which the number corresponds to one AOBU, an AOBU is generated in step S104.

If the input data is RTI data having additional data related to audio data in the step S102, the RTI data is processed to form an RTI pack RTI_PCK in step S105. In the RTI pack RTI_PCK, text data and an extra header such as the reproducing time information are included. The RTI pack RTI_PCK generated in the step S105 is placed in a predetermined location inside the AOBU formed in the step S104 to generate a new AOBU in step S106.

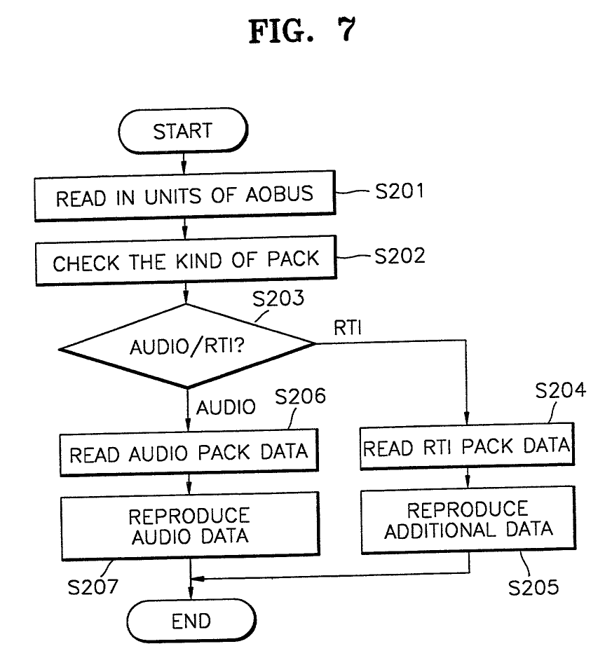

FIG. 7 is flowchart showing a reproducing method according to an embodiment of the present invention.

Referring to FIG. 7, data is read from a recording medium in units of AOBUs in step S201. The kind of packs included in the read AOBU is checked in step S202. Whether the read pack is an RTI pack RTI_PCK or an audio pack A_PCK is determined in step S203. If the read pack is an RTI pack RTI_PCK, RTI pack RTI_PCK data is read in step S204 and additional data included in the RTI pack RTI_PCK is reproduced in step S205. At this time, the additional data is reproduced after being synchronized to audio data in the corresponding AOBU, based on synchronization information stored as an extra header in the RTI pack RTI_PCK, that is, reproducing-time information.

If the result of the step S203 indicates that the read pack is an audio pack A_PCK, audio pack A_PCK data in the AOBU is read in step S206 and audio data is reproduced in step S207.

According to the present invention as described above, since audio data and related additional data are independently or separately recorded in the same basic recording unit (AOBU), the recording/editing/reproducing of additional data becomes easier. Also, according to the present invention, a user can additionally record additional information such as a text in audio data, and can reproduce the additional information together with audio data.

Although a few preferred embodiments of the present invention have been shown and described, it would be appreciated by those skilled in the art that changes may be made in this embodiment without departing from the principles and spirit of the invention, the scope of which is defined in the claims and their equivalents.

What is claimed is:

1. A recording medium comprising:
predetermined recording units in which audio data is recorded, and additional data related to the audio data is recorded in a predetermined location in corresponding ones of the recording units of the audio data.

2. The recording medium of claim 1, wherein each recording unit has at least one audio pack in which the audio data is recorded, and the additional data is recorded separately from the related at least one audio pack.

3. The recording medium of claim 2, wherein the additional data is recorded in the corresponding recording unit so as to be reproduced in relation to the related at least one audio pack.

4. The recording medium of claim 2, wherein the additional data is recorded in real-time information packs which is to be real-time reproduced by being synchronized to the related audio data included in the corresponding audio packs.

5. The recording medium of claim 4, wherein the additional data comprises text data, and the real-time information form corresponding real-time text information (RTI) packs each having the text data and synchronization information of the text data corresponding to the related audio data included in the same recording unit.

6. The recording medium of claim 5, wherein the synchronization information comprises reproducing-time information of the text data, and the reproducing-start time of the text data is located in a reproducing duration of the same recording unit.

7. The recording medium of claim 1, wherein the additional data is formed in units of real-time text information (RTI) packs, and each recording unit has a plurality of the audio packs and one of the RTI packs positioned at a first position in the recording unit.

8. The recording medium of claim 1, wherein the additional data is formed in units of real-time text information (RTI) packs, and each recording unit has a plurality of the audio packs and one of the RTI packs positioned at a second position in the recording unit after one of the audio packs positioned at a first position in the recording unit.

9. A recording method of recording audio data and additional data related to the audio data, the recording method comprising:
recording the audio data in predetermined recording units; and
recording the additional data in a predetermined location in corresponding ones of the recording units.

10. The method of claim 9, wherein each recording unit includes at least one audio pack in which the audio data is recorded, and the additional data is recorded separately from the related at least one audio pack.

11. The method of claim 10, wherein the recording of the additional data comprises recording the additional data so as to be reproduced in relation to the related at least one audio pack.

12. The method of claim 11, wherein the additional data is recorded in real-time information packs which is to be real-time reproduced by being synchronized to the related audio data included in the corresponding audio packs.

13. The method of claim 12, wherein the additional data comprises text data, and the real-time information packs are real-time text information (RTI) packs each having the text data and synchronization information of the text data corresponding to the related audio data included in the same recording unit.

14. The recording medium of claim 9, wherein the additional data is formed in units of real-time text information (RTI) packs, and each recording unit has a plurality of the audio packs and one of the RTI packs positioned at a first position in the recording unit.

15. The recording medium of claim 9, wherein the additional data is formed in units of real-time text information (RTI) packs, and each recording unit has a plurality of the audio packs and one of the RTI packs positioned at a second position in the recording unit after one of the audio packs positioned at a first position in the recording unit.

16. A reproducing method of reproducing data from a recording medium wherein audio data is recorded in predetermined recording units and additional data related to the audio data is recorded in a predetermined location in the corresponding recording units of the audio data, the reproducing method comprising:
reading data from the recording medium in units of the recording units; and
reproducing the audio data and the additional data recorded in the read recording units, after relating the additional data to the audio data.

17. The method of claim 16, wherein each recording unit has at least one audio pack in which the audio data is recorded, and the additional data is recorded separately from the related at least one audio pack.

18. The method of claim 17, wherein the additional data is recorded in the corresponding recording unit so as to be reproduced in relation to the related at least one audio pack.

19. The method of claim 18, wherein the additional data is recorded in real-time information packs as real-time information on the recording medium, and the reproducing of the audio data and the additional data comprises real-time reproducing the additional audio data by synchronizing the additional data to the related audio data included in the same recording unit.

20. The method of claim 19, wherein the additional data comprises text data, and the real-time information pack are real-time text information (RTI) packs each having the text data and synchronization information of the text data corresponding to the related audio data included in the same recording unit.

21. The method of claim 19, wherein the synchronization information comprises reproducing-time information of the text data, and the reproducing-start time of the text data is located in a reproducing duration of the recording unit.

22. The method of claim 16, wherein the additional data is formed in units of real-time text information (RTI) packs, and each recording unit has a plurality of the audio packs and one of the RTI packs positioned at a first position in the recording unit.

23. The method of claim 16, wherein the additional data is formed in units of real-time text information (RTI) packs, and each recording unit has a plurality of the audio packs and one of the RTI packs positioned at a second position in the recording unit after one of the audio packs positioned at a first position in the recording unit.

24. A recording apparatus comprising:
an audio signal processor encoding input audio data to generate at least one audio pack, and combining the at least one audio pack to generate an audio object unit (AOBU) that is a predetermined recording unit;
a real-time text information (RTI) signal processor encoding additional data related to the audio data to generate an RTI pack;
a multiplexor generating a new AOBU having the additional data by including the RTI pack provided from the RTI signal processor in the AOBU provided from the audio signal processor; and
a recording controller recording the AOBU generated by the multiplexor.

25. The recording apparatus of claim 24, wherein the multiplexor multiplexes the at least one audio pack and the RTI pack so that the additional data recorded in the RTI pack is reproducible in relation to the audio data included in the new AOBU.

26. The recording apparatus of claim 25, wherein the RTI pack has text data and synchronization information of the text data corresponding to the audio data included in the new AOBU.

27. The recording apparatus of claim 26, wherein the synchronization information includes reproducing-time information of the text data, and the reproducing-start time of the text data is located in a reproducing duration of the new AOBU.

28. The recording apparatus of claim 24, wherein the audio signal processor combines a plurality of the audio packs to generate the AOBU, and the multiplexor inserts the RTI pack at a first position in the AOBU.

29. The recording apparatus of claim 24, wherein the audio signal processor combines a plurality of the audio packs to generate the AOBU, and the multiplexor inserts the RTI pack at a second position in the AOBU after one of the audio packs positioned at a first position in the AOBU.

30. A reproducing apparatus for reproducing data from a recording medium wherein audio data is recorded in predetermined recording units and additional data related to the audio data is recorded in a predetermined location in the recording unit of the audio data, the reproducing apparatus comprising:
a reproducing controller reading an audio object unit (AOBU) which is one of the recording units;
a demultiplexor demultiplexing an audio pack in which audio data is recorded and an RTI pack in which additional data is recorded, from the read AOBU;
an audio signal processor decoding the audio pack demultiplexed by the demultiplexor to output the audio data stored in the audio pack; and
an RTI signal processor decoding the RTI pack demultiplexed by the demultiplexor to output additional data stored in the RTI pack in relation to the audio data from the audio pack.

31. The reproducing apparatus of claim 30, wherein the RTI signal processor outputs text data included in the RTI pack after synchronizing the text data to the audio data from the audio pack.

32. The reproducing apparatus of claim 30, wherein the demultiplexor demultiplexes a plurality of audio packs from the read AOBU, and the RTI pack at a first position in the read AOBU.

33. The recording and/or reproducing apparatus of claim 32, wherein the demultiplexor demultiplexes a plurality of audio packs from the read AOBU, and the RTI pack at a second position in the read AOBU after one of the audio packs positioned at a first position in the read AOBU.

34. A recording and/or reproducing apparatus comprising:
an audio signal processor encoding input audio data to generate at least one audio pack and combining the at least one audio pack to generate an audio object unit (AOBU) which is a predetermined recording unit, when data is recorded, and
decoding the at least one audio pack demultiplexed from a new AOBU by a demultiplexor to output the audio data, when the data is reproduced;
a real-time text information (RTI) signal processor encoding additional data related to the audio data to generate an RTI pack which is an additional pack when the data is recorded, and decoding the RTI pack demultiplexed from the new AOBU by the demultiplexor to output the additional data in relation to the audio data when the data is reproduced;
a multiplexor/demultiplexor including the RTI pack provided from the RTI signal processor in the AOBU provided from the audio signal processor to generate a new AOBU having the additional data, and when the data is reproduced, demultiplexing the at least audio pack in which audio data is recorded and RTI pack in which the additional data is recorded, from the new AOBU; and
a recording/reproducing controller recording the new AOBU generated by the multiplexor on a recording medium, reading the new AOBU, which is a recording unit, from the recording medium, and providing the new AOBU to the multiplexor/demultiplexor.

35. The recording and/or reproducing apparatus of claim 32, wherein the RTI pack has text data and synchronization information of the text data corresponding to the audio data included in the AOBU.

36. The recording and/or reproducing apparatus of claim 33, wherein the synchronization information comprises reproducing-time information of the text data, and the reproducing-start time of the text data is located in a reproducing duration of the new AOBU.

37. The recording and/or reproducing apparatus of claim 34, wherein the audio signal processor generates a plurality of the audio packs to generate the AOBU and the multiplexor/demultiplexor inserts the RTI pack at a first position in the AOBU, when the data is recorded.

38. The recording and/or reproducing apparatus of claim 34, wherein the audio signal processor generates a plurality of the audio packs to generate the new AOBU, and the multiplexor/demultiplexor inserts the RTI pack at a second position in the AOBU after one of the audio packs positioned at a first position in the AOBU, when the data is recorded.

39. A recording medium comprising:
recording units each comprising
at least one audio pack having audio data, and
a real-time text information (RTI) pack in a predetermined location within the recording unit;
wherein at least some of the RTI packs have additional data related to the audio data within the same recording unit.

40. The recording medium of claim 39, wherein ones of the RTI packs have no information recorded therein.

41. The recording medium of claim 39, wherein the RTI packs with the additional data comprise:
the text data relating to the audio data in the same recording unit; and
an extra header having synchronization information to synchronize the text data with the audio data in the same recording unit.

42. The recording medium of claim 41, wherein the recording units are audio object units (AOBUs).

43. The recording medium of claim 41, wherein:
the recording units each comprise reproducing-start time information and reproducing-end time information for the AOBU; and
the synchronization information comprises reproducing-start time information of the text data.

44. A recording medium comprising:
recording units in which audio data and additional data relating to the audio data are separately or independently recorded in same ones of the recording units.

45. The recording medium of claim 44, wherein each recording unit comprises:
at least one audio pack having the audio data; and
an additional data pack having the additional data relating to the audio data in the at least one audio pack.

46. A method of recording audio data and additional data relating to the audio data, comprising:
separately or independently recording the audio data and the additional data in same ones of predetermined units; and
recording the predetermined units on a recording medium.

47. The method of claim 46, wherein the separately or independently recording comprises:
recording at least one audio pack in each of the predetermined units; and
recording a real-time information (RTI) pack in a predetermined location in each one of the predetermined units, wherein at least some of the RTI packs have the additional data relating to the audio data in the same ones of the predetermined units.

48. A method of reproducing audio data and additional data relating to the audio data which are recorded separately or independently in same ones of predetermined recording units, the method comprising:
reading the predetermined recording units; and
demultiplexing the predetermined units to separate the audio data from the additional data.

49. The method of claim 48, wherein the predetermined recording units each comprise at least one audio pack having the audio data and a real-time information (RTI) pack, wherein at least some of the RTI packs have the additional data relating to the audio data in the same ones of the predetermined units, the demultiplexing comprising:
separating the at least one audio pack for audio processing from the RTI pack for real-time information processing.

50. A recording apparatus comprising:
an audio signal processor encoding input audio data to generate audio packs, and combining pluralities of the audio packs to generate recording units;
a real-time text information (RTI) processor generating RTI packs, at least some of which have additional data relating to the audio data;
a multiplexor generating each of the predetermined units by combining one of the pluralities of audio packs with one of the RTI packs; and
a recording controller recording the predetermine units on a recording medium.

51. A reproducing apparatus for reproducing data from a recording medium, wherein the recording medium has recording units each having audio packs a real-time text information (RTI) pack, the reproducing apparatus comprising:
a reproducing controller reading the recording units from the recording medium; and combining pluralities of the audio packs to generate recording units;
a demultiplexor demultiplexing the audio packs from the RTI pack for each recording unit;
an audio signal processor decoding the audio packs demultiplexed by the demultiplexor; and
an (RTI) processor decoding the RTI packs demultiplexed by the demultiplexor.
